(19) United States
(12) Patent Application Publication
(10) Pub. No.: US 2024/0360556 A1
(43) Pub. Date: Oct. 31, 2024

(54) DEPOSITION HEAD FOR TUBULAR/NON-PLANAR COATINGS

(71) Applicants: CENTRE NATIONAL DE LA RECHERCHE SCIENTIFIQUE, Paris (FR); INSTITUT POLYTECHNIQUE DE GRENOBLE, Grenoble (FR)

(72) Inventors: David MUNOZ ROJAS, Grenoble (FR); Fidel TOLDRA REIG, Grenoble (FR)

(21) Appl. No.: 18/566,278

(22) PCT Filed: Jun. 1, 2022
(86) PCT No.: PCT/EP2022/064931

§ 371 Date: Dec. 1, 2023

(30) Foreign Application Priority Data
Jun. 2, 2021 (FR) FR2105790

(51) Int. Cl. C23C 16/455; B33Y 10/00; B33Y 80/00

(52) U.S. Cl. CPC C23C 16/45551; B33Y 10/00; B33Y 80/00; C23C 16/45517

(57) ABSTRACT

The invention relates to a chemical vapor deposition head of a tubular substrate comprising:
a first opening for receiving a first precursor,
a second opening for receiving a second precursor,
a third opening for receiving an inert gas stream,
a first distribution duct network connecting the first opening to a first group of holes extending over an inner section of the head,
a second distribution duct network connecting the second opening to a second group of holes extending over the inner section of the head,
a third distribution duct network connecting the third opening to a third group of holes extending over the inner section of the opening, a hole of the first or second group of holes being adjacent on either sides to a hole of the third group of holes,
   the first, second, and third distribution duct networks each having at least one first, second, and third expansion prechamber, the tubular substrate performing a relative back-and-forth movement.

The present application is a U.S. National Phase of International Application Number PCT/EP2022/064931, filed Jun. 1, 2022, which claims priority to French Application No. 2105790, filed Jun. 2, 2021.

### DOMAIN OF THE INVENTION

The invention relates to a head for depositing thins layers in the vapor phase, and more particularly to a deposition head suitable for implementing the SALD (Spatial Atomic Layer Deposition) technique. The invention also relates to a thin film deposition system comprising such a head.

### TECHNOLOGICAL BACKGROUND

Atomic Layer Deposition (ALD) is a chemical vapor deposition (CVD) technique developed in the 1960-70s that offers the unique possibility of depositing high-quality thin layers at low temperatures, with precise thickness control, exceptional uniformity and excellent coverage even in the presence of steps with a high aspect ratio. This is due to the spontaneously self-limiting nature of ALD growth, which occurs directly and selectively on the sample surface when sequentially exposing different precursors transported by inert gas streams (typically N₂ or Ar). Thus, whereas in traditional chemical vapor deposition techniques the precursors are injected at the same time and react on the substrate by thermal or plasma activation, in the case of ALD the precursors are injected by consecutive pulses, separated in time by purges with inert gas or “vacuum”, thus allowing the selective and spontaneously resolving surface nature of the technique.

Since the 1990s, ALD has become the technology of choice in the semiconductor and large screen industries. Later, the advent of nanoscience and nanotechnology extended the use of ALD to research laboratories.

Despite its unique advantages, ALD has two major drawbacks that have limited its industrial application: the slowness of deposition and the need to operate in a vacuum. As a result, ALD is currently only used in industries where no other technique is available.

Spatial ALD (SALD) provides a solution to the problem of “conventional” ALD slowness. This technique, originally proposed by T. S Suntola et al. in U.S. Pat. No. 4,389,973, involves separating the precursors in space rather than in time. Thus, in SALD, the precursors are continuously delivered to different portions of the substrate surface, separated by an inert gas zone, while the sample moves from one precursor location to the other passing through the inert gas zone. This increases the deposition rate by up to two orders of magnitude. Furthermore, it has been demonstrated that by arranging the SALD deposition head in close proximity (100 μm or less) to the deposition surface and equipping it with gas suction openings, it is possible to operate at ambient pressure, and therefore outside a vacuum chamber. This is referred to as ambient pressure SALD (AP-SALD).

However, spatial ALD currently has limitations, since this deposition technique is mainly suitable for application on a flat or partially planar surface, i.e. a flexible surface that can be flattened and for powder deposition. However, depositing thin films on non-planar substrates and, more particularly tubular substrates, is very advantageous since tubular substrates have a number of advantages over planar substrates. Indeed, the area/volume ratio is higher, reflecting better coating application, and these types of substrates can easily be used in a modular configuration, favoring their industrial applicability. However, the deposition of thin films on tubular substrates using traditional thin film deposition techniques, namely traditional ALD and spatial ALD, is complex and costly. In addition, using a SALD or spatial ALD design, adapted to the tubular design, would allow the advantages of this type of technology to be used for these types of non-planar substrates. However, at the current time no spatial ALD technology is suitable for coating tubes.

In the case of spraying and pulsed laser deposition, a special configuration needs to be added to the system to ensure total surface deposition. This involves a rotating element and a heat source that keeps the temperature of the substrate to be incorporated constant. In addition, these techniques involve the use of a “vacuum” for the deposition. In the case of ALD, if a tube is used, additional steps need to be carried out because the entire chamber is exposed to the precursors. The tubes then need to be sealed to prevent deposits on the outside and inside.

Conversely, other techniques can replace ALD and spatial ALD for tubular substrates. Techniques such as dip coating, spray coating or electroplating offer a less costly procedure for depositing films on a macroscopic scale on tubes, but they require post-thermal treatments to sinter the films and the films are not completely homogeneous, compliant, and dense. Lastly, these technologies are limited in terms of the minimum achievable coating thickness. Furthermore, as stated previously, these techniques are only applicable to the deposition of macroscopic scale films onto tubes.

The invention aims to address all or some of the aforementioned problems by proposing a new deposition head for tubular and non-planar coatings that can be used for deposition in vapor deposition (CVD) and atomic layer deposition (ALD) processes, including spatial ALD. One of the advantages of this deposition head is that it can be operated outdoors without the need for a vacuum around the substrate. The invention makes it possible to deposit compliant thin films onto tubular substrates with perfect control of the thickness and homogeneity. The invention thus proposes a simple and inexpensive device for producing high-quality films to meet industrial requirements.

### SUMMARY

To this end, the subject-matter of the invention is a head for the chemical vapor deposition of a tubular substrate comprising:
a first opening for receiving a first inlet gas stream transporting a first precursor,
a second opening for receiving a second inlet gas stream transporting a second precursor,
a third opening for receiving a third inlet inert gas stream,
a first network of distribution ducts connecting the first opening of the first gas stream to a first group of holes extending over an inner section of the deposition head,
a second network of distribution ducts connecting the second opening of the second gas stream to a second group of holes extending over the inner section of the deposition head,
a third network of distribution ducts connecting the third opening of the third inert gas stream to a third group of holes extending over the inner section of the deposition head, a hole of the first or second group of holes being adjacent on either side to a hole of the third group of holes along an axis of rotation R of the deposition head,
   the first, second, and third distribution duct networks having respectively at least one first, second and third expansion prechamber included in the deposition head, the tubular substrate performing a relative back-and-forth movement along the axis of rotation R of the deposition head.

According to one aspect of the invention, the at least one first, second and third expansion prechambers extend successively in a direction of the axis of rotation R of the deposition head.

According to one aspect of the invention, the at least one first expansion prechamber of the first distribution duct network is connected to the first group of holes via a first channel, the internal volume of the first channel being smaller than the volume of the at least one first expansion prechamber of the first distribution duct network, the at least one second expansion prechamber of the second distribution duct network is connected to the second group of holes via a second channel, the internal volume of the second channel being smaller than the volume of the at least one second expansion prechamber of the second distribution duct network, wherein the at least one expansion prechamber of the third distribution duct network is connected to the third group of holes via a third channel, the internal volume of the third channel being smaller than the volume of the at least one third expansion prechamber of the third distribution duct network.

According to one aspect of the invention, the first, second, and third distribution ducts are non-intersecting.

According to one aspect of the invention, the deposition head comprises a fourth distribution duct connected to a fourth group of holes extending over the inner section of the deposition head, the fourth duct enabling the evacuation of the third inert gas stream to a fourth discharge opening of the deposition head.

According to one aspect of the invention, the holes of the first, second and third groups of holes are straight slots parallel to each other.

According to one aspect of the invention, a deposition distance between the holes of the first, second and third groups of holes and the tubular substrate, inserted into the deposition head, is less than two hundred micrometers.

According to one aspect of the invention, a deposition distance between the holes of the first, second and third groups of holes and the tubular substrate, inserted into the deposition head, is greater than fifty micrometers.

According to one aspect of the invention, the deposition head comprises a first stream receiving face comprising the first, second and third openings and a second stream receiving face comprising first, second and third secondary stream openings, respectively mirroring the first, second and third openings of the first receiving face according to a plane P passing perpendicularly through the axis of rotation R of the deposition head.

According to one aspect of the invention, the first gas stream is an oxidizing precursor.

According to one aspect of the invention, the first gas stream is a metal precursor.

The invention also relates to a system for chemical vapor deposition of a tubular substrate comprising at least two deposition heads.

The invention also relates to a computer program product comprising computer-executable instructions which, when executed by a processor, cause the processor to order an additive manufacturing device to manufacture the deposition head.

The invention also relates to a method of manufacturing the deposition head by additive manufacturing, the method comprising the following steps: obtaining an electronic file representing a geometry of a product in which the product is the deposition head and controlling an additive manufacturing device to manufacture, on one or more additive manufacturing steps, the product according to the geometry specified in the electronic file.

### BRIEF INTRODUCTION OF THE DRAWINGS

The invention will be better understood and further advantages will become apparent from the detailed description of a given exemplary embodiment, the description illustrated by the accompanying drawing in which:

FIG. 1 shows a schematic view of a deposition head according to the invention;

FIG. 2 shows a schematic cross-sectional view of the deposition head according to the invention;

FIG. 3 shows a schematic side view of the deposition head according to the invention;

FIG. 4 shows a schematic view of the deposition head according to one variant of the invention;

FIG. 5 shows a method of manufacturing the deposition head according to the invention.

For the sake of clarity, the same elements will bear the same reference signs in the various figures.

### DETAILED DESCRIPTION

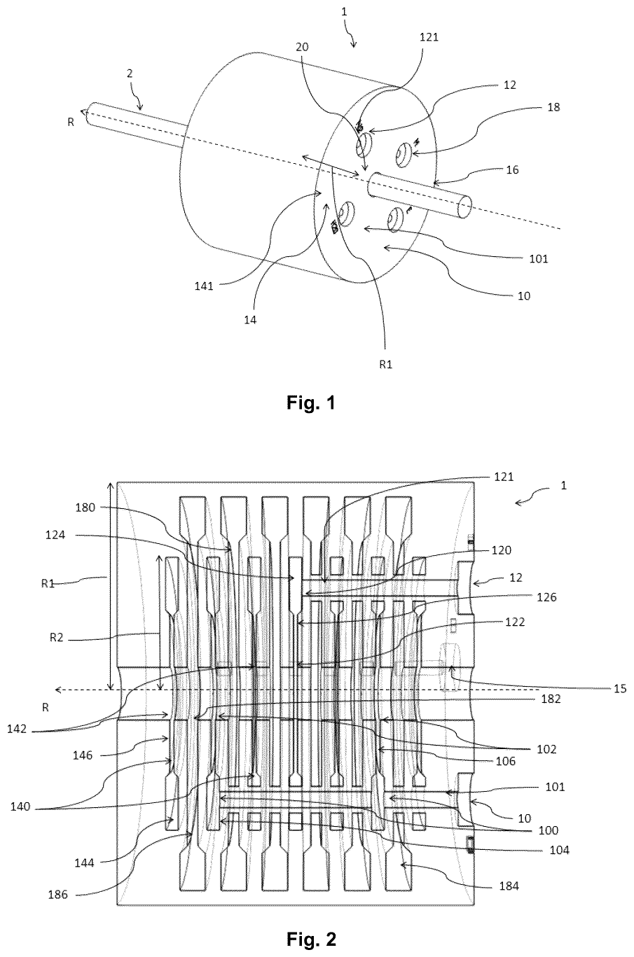

FIG. 1 shows a schematic view of a chemical deposition head 1 capable of depositing, in the vapor phase, a coating layer on a tubular substrate 2 according to the invention. The deposition head 1 has the form of a cylinder of radius R1 extending along an axis of rotation R and having a cross-section between an inner surface 15 (as shown in FIG. 2) and an outer surface 13 (as shown in FIG. 4) allowing the insertion of the tubular substrate 2. The deposition head 1 comprises:
a first opening 10 for receiving a first inlet gas stream transporting a first precursor, preferably a gas charged with a first precursor, for example an oxidizing precursor such as water vapor (H₂O),
a second opening 12 for receiving a second inlet gas stream transporting a second precursor, preferably a gas charged with a second precursor, for example a metallic precursor or an organometallic compound such as Al(CH₃)₃,
a third opening 14 for receiving a third inert gas stream or an inlet inert gas, such as nitrogen N₂ or argon Ar.

The deposition head 1 may also comprise a fourth opening 18 for evacuating a fourth gas stream. More precisely, the fourth opening 18 enables the evacuation of the inert gas introduced into the third opening 14.

The first 10, second 12, third 14 and fourth 18 openings are located on a first receiving face 16, of circular shape. In a preferred configuration, the first receiving face 16 is perpendicular to the axis of rotation R. The first opening 10, the second opening 12 and the third opening 14 respectively precede a first inlet volume 101, a second inlet volume 121 and a third inlet volume 141. The first inlet volume 101, the second inlet volume 121 and the third inlet volume 141 have the form of a hollow cylinder starting against the first receiving face 16 at the first opening 10, the second opening 12 and the third opening 14 respectively and extending parallel to the axis of rotation R.

In addition, the deposition head 1 may comprise a fifth or sixth opening (not shown) in the case of depositing more complex materials with different metals, such that different precursors can be injected.

Furthermore, the deposition head 1 comprises an insertion hole 20 of the tubular substrate 2 positioned in the center of the first receiving face 16 and coincides with the axis of rotation R. This insertion hole 20 therefore continues into the deposition head 1 so as to take the form of an “empty cylinder” allowing the complete insertion of the tubular substrate 2. By way of illustration, the insertion hole 20 is similar in shape to the tubular substrate 2. Thus, in the case of a cylindrical tubular substrate 2, the insertion hole 20 can have a circular shape so as to obtain the hollow cylinder described above. Nonetheless, it may be possible to have an octagonal or oval-shaped insertion hole 20 so as to have a complementary shape with a potentially octagonal or oval-shaped tubular substrate 2.

The deposition head also comprises, as shown in FIG. 2, a first network of distribution ducts 100 connecting the first opening 10 of the first gas stream to a first group of holes 102, a second network of distribution ducts 120 connecting the second opening 12 of the second gas stream to a second group of holes 122, and a third network of distribution ducts 140 connecting the third opening 14 of the third inert gas stream to a third group of holes 142. Each hole of the first 102, second 122 and third 142 groups of holes extends over an inner section 15 of the deposition head 1 and is aligned along the axis of rotation R. By way of illustration, the first inlet volume 101, the second inlet volume 121 and the third inlet volume 141 are respectively included in the first distribution duct network 100, the second distribution duct network 120 and the third distribution duct network 140. The first 100, second 120 and third 140 distribution ducts are non-intersecting.

In addition, a hole of the first 102 or the second 122 group of holes is only adjacent, on either side according to the axis of rotation R, to a hole of the third group of holes 142. Thus, each hole of the first group 102 of holes is adjacent along the axis of rotation R to two holes on either side of the third group 142 of holes. And similarly, each hole of the second group 122 of holes is adjacent along the axis of rotation R to two holes on either side of the third group 142 of holes.

Indeed, this arrangement of the holes makes it possible to ensure the separation between the first precursor and the second precursor from the action of the inert gas. Thus, when the first precursor is applied to the tubular substrate 2 via the first group of holes 102, the first precursor is limited on each side by the inert gas, which becomes a spatial limiter, itself applied to the tubular substrate 2 via the third group of holes 142. And, similarly, when the second precursor is applied to the tubular substrate 2 via the second group of holes 122, the second precursor is limited on either side by the inert gas itself applied to the tubular substrate 2 via the third group of holes 142. Thus, the first precursor and the second precursor are never brought into contact when the latter are applied on the tubular substrate 2.

The first 100, second 120 and third 140 distribution duct networks respectively have at least one first 104, second 124 and third 144 expansion prechamber included in the deposition head 1. The first expansion prechamber 104, the second expansion prechamber 124 and the third expansion prechamber 144 are in the form of a hollow ring arranged inside the deposition head 1 and have a radius R2 smaller than the radius R1 of the hollow cylinder formed by the deposition head 1. Thus, the at least one first expansion prechamber 104 is directly connected to the first opening 10 via the first inlet volume 101 so as to be able to expand the first precursor that has previously been introduced via the first opening 10 and has passed through the first inlet volume 101. Similarly, at least one second expansion prechamber 124 is directly connected to the second opening 12 via the second inlet volume 121 so as to be able to expand the second precursor that was previously introduced via the second opening 12 and that has passed through the second inlet volume 121 and the at least one third expansion prechamber 144 is directly connected to the third opening 14 via the second inlet volume 141 so as to be able to expand the inert gas which was previously introduced via the third opening 14 and which has passed through the third inlet volume 121.

By way of illustration, the at least one first expansion prechamber 104, the at least one second expansion prechamber 124 and the third expansion prechamber 144 extend successively in the direction of the axis of rotation R of the deposition head 1 and thus form a succession of hollow rings with the same radius R2 along the axis of rotation R.

In addition, the at least one first expansion prechamber 104 of the first distribution duct network 100 is connected to the first group of holes 102 via at least one first channel 106. Similarly, the at least one second expansion prechamber 124 of the second distribution duct network 120 is connected to the second group of holes 122 via at least one second channel 126 and the at least one third expansion prechamber 144 of the third distribution duct network 140 is connected to the third group of holes 142 via at least one third channel 146.

The concentric prechambers, namely the first expansion prechamber 104, the second expansion prechamber 124 and the third expansion prechamber 144, are necessary to ensure proper homogenization of the gas pressure and its correct distribution in each channel, namely the first channel 106, the second channel 126 and the third channel 146.

In addition, it may be possible to determine suitable ratios between the volumes of the first expansion prechambers 104, second expansion prechambers 124 and third expansion prechambers 144 and the outlet volumes of the first channels 106, second channels 126 and third channels 146 in order to provide optimum gas pressure distributions.

To this end, the internal volume of the at least one first channel 106 is smaller than the volume of the at least one first expansion prechamber 104 of the first distribution duct network 100, the internal volume of the at least one second channel 126 is smaller than the volume of the at least one second expansion prechamber 124 of the second distribution duct network 120, and the internal volume of the at least one third channel 146 is smaller than the volume of the at least one third expansion prechamber 144 of the third distribution duct network 140. It is then possible, for a person skilled in the art, to define a first ratio between the volume of the at least one first channel 106 and the volume of the at least one first expansion prechamber 104, a second ratio between the volume of the at least one second channel 126 and the volume of the at least one second expansion prechamber 124 and a third ratio between the volume of the at least one third channel 146 and the at least one third expansion prechamber 144. The first, second and third ratios may thus be identical or different depending on the configuration of the deposition head 1, bearing in mind that equality between the first and second ratio does not mean equality between the volumes of the first 106 and second 126 channels and the first 104 and second 124 expansion prechambers.

In addition, for a constant flow rate applied in the first expansion prechambers 104, second expansion prechambers 124 and third expansion prechambers 144, experience shows that a small prechamber volume produces a very inhomogeneous gas distribution along the first channels 106, second channels 126 and third channels 146 and particularly at the first groups of holes 102, second groups of holes 122 and third groups of holes 142. By way of illustration, it may be envisaged to have a constant flow rate in the first expansion prechambers 104, second expansion prechambers 124 and third expansion prechambers 144 of approximately 100 mL/min.

However, the calculations also show that the homogeneity of the gas stream distribution can be substantially improved by increasing the volume of the first expansion prechambers 104, second expansion prechambers 124 and third expansion prechambers 144, and that very good homogeneity can be achieved for large volumes of first expansion prechambers 104, second expansion prechambers 124 and third expansion prechambers 144 with, by way of illustration, radii of 1.4 mm and 2 mm. Therefore, a volume ratio or ratio between the volume of the first expansion prechambers 104, second expansion prechambers 124 and third expansion prechambers 144 and the volume of the first channels 106, second channels 126 and third channels 146 of at least 0.7 must be respected.

By way of illustration, in order to have a homogeneous distribution of pressure in the first 100, second 120 and third 140 distribution ducts, the first, second and third ratios must be greater than or equal to 0.71 and may be, in a preferred configuration, between 1.36 and 41.89. In this way, a homogeneous distribution of the pressure makes it possible to ensure a homogeneous distribution of the first and second precursors and the inert gas in the first 100, second 120 and third 140 distribution ducts so that all of the first 106, second 126 and third 146 channels are all irrigated. However, the dimensions of this configuration are only illustrative. This distribution also depends on the number of ducts and the size of the deposition head 1.

The first group of holes 102, the second group of holes 122 and the third group of holes 142 can have the form of straight slots parallel to one another. The first group of holes 102, the second group of holes 122 and the third group of holes 142 thus face the tubular substrate 2 when the tubular substrate 2 is inserted into the insertion hole 20 of the deposition head 1. In this manner, the first precursor can be applied, via the first group of holes 102, to the tubular substrate 2. Just like the second precursor, which can be applied to the tubular substrate 2 via the second group of holes 122 and the inert gas which can be applied to the tubular substrate 2 via the third group of holes 142.

Furthermore, in order to optimize the coating of the tubular substrate 2 by the first and/or second precursor, limited by the inert gas, the holes of the first 102, second 122 and third 142 groups of holes and the tubular substrate 2, inserted into the deposition head 1, are spaced apart by a deposition distance of less than two hundred micrometers and more than fifty micrometers in order to allow the first and/or second precursor to be applied. In addition, this deposition distance also depends on the precursor or inert gas stream rate, the sizing of the tubular substrate 2 or the deposition technique, such as for example CVD or ALD. Depending on the desired configuration, the deposition head 1 can be adapted. Thus, the deposition distance of the precursors and the inert gas and the dimensions of the first 100, second 120 and third 140 distribution ducts are adjusted to control the desired type of deposition on the tubular substrate 2, i.e. to perform the ALD deposition or the CVD deposition.

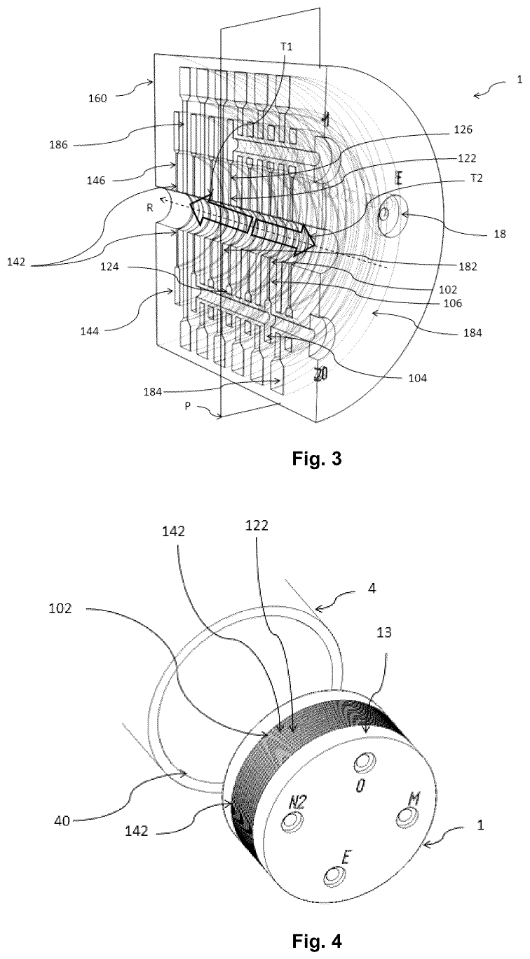

The deposition head 1 also comprises a fourth distribution duct 180 connected to the fourth discharge opening 18. More precisely, the fourth distribution duct 180 is formed by at least one fourth channel 186 allowing the surplus inert gas at the level of the tubular substrate 2 to be evacuated through a fourth group of holes 182 connected to the at least one fourth channel 186 and extending over the inner section 15 of the deposition head 1. At the other end of the at least one fourth channel 186 is an inert gas evacuation tank 184 which is itself connected to the fourth inert gas discharge opening 18. Like an expansion prechamber, the reservoir 184 comprises a hollow volume capable of holding the surplus inert gas before it is evacuated through the fourth discharge opening 18, as shown in FIG. 3. In general, a hole of the fourth group of holes 182 is placed between a hole of the first 102 or second 122 group of holes and a hole 142 of the third group of holes. In this way, excess inert gas and/or precursors are always evacuated.

In addition, the tubular substrate 2, installed in the deposition head 1 via the insertion hole 20, needs to perform a relative “back-and-forth” movement along the axis of rotation R of the deposition head relative to the deposition head 1. This back-and-forth movement results in a transverse oscillation along the axis of rotation R and more precisely, in a successive manner, a first translation T1 in one direction of the axis of rotation R and a second translation T2 in a direction opposite to the direction of the axis of rotation R. Indeed, this back-and-forth movement relative to the deposition head 1 is necessary to allow optimum coverage of the tubular substrate 2 inserted into the deposition head 1 by the first and second precursors separated by the inert gas. Thus, the tubular substrate 2 can undergo this “back-and-forth” movement while the deposition head 1 is stationary, or according to another covering configuration, the deposition head 1 can undergo this “back-and-forth” movement in order to cover the tubular substrate 2 which is then stationary. It can also be envisaged that the deposition head 1 and the tubular substrate 2 undergo this “back-and-forth” movement out of phase. In a certain case of coating, a single “back-and-forth” movement may be necessary to perform the deposition of the coating on the tubular substrate 2, as for example in the case of adding a thin coating on the tubular substrate 2.

According to one configuration of the deposition head 1, the deposition head 1 comprises the first stream receiving face 16 comprising the first 10, second 12, third 14 and fourth 18 openings and a second stream receiving face 160 of identical shape to the first receiving face 16, perpendicular to the axis of rotation R and parallel to the first receiving face 16. The second receiving face 160 can comprise, like the first receiving face 16, a first secondary opening, a second secondary opening and a third secondary opening for the stream, respectively mirroring the first 10, second 12 and third 14 openings of the first receiving face 16 in a plane P passing perpendicularly through the axis of rotation R of the deposition head 1.

Thus, the first secondary opening allows the introduction of the first precursor, the second secondary opening allows the introduction of the second precursor and the third secondary opening allows the introduction of the inert gas. This configuration thus makes it possible to limit the pressure necessary to introduce the different streams into the deposition head, since each stream is introduced at both ends, i.e. the first receiving face 16 and the second receiving face 160, of the deposition head 1 and no longer at just one end.

According to another configuration of the deposition head 1 shown in FIG. 4, requiring coating of an inner part 40 of a hollow tubular substrate 4, it can be envisaged that the deposition head 1 is inserted into the hollow tubular substrate 4. In this case, the holes of the first group of holes 102, the second group of holes 122 and the third group of holes 142 are positioned on an outer face 13, extending over the section of the cylinder represented by the deposition head 1, so as to always face the hollow tubular substrate 4 when the deposition head 1 is inserted therein. Therefore, since the back-and-forth movement necessary for the deposition of the first and second precursors is relative between the deposition head 1 and the hollow tubular substrate 4, the person skilled in the art can choose to perform a back-and-forth movement on the hollow tubular substrate 4 by holding the deposition head 1 still or on the deposition head 1 by holding the hollow tubular substrate 4 still.

The deposition head 1 according to the invention therefore comprises a surface, i.e. the inner surface 15 or the outer surface 13, configured to enable the deposition of the first gas stream, the second gas stream and the third inert gas stream onto the tubular substrate 2. The inner surface 13 and the outer surface 15 both have a cylindrical shape or are similar to the associated tubular substrate. Thus, it may be envisaged, as indicated previously, to use an octagonal or oval tubular substrate 2.

Thus, when the deposition is performed via the inner surface 15 onto the tubular substrate 2, via the holes of the first group of holes 102, the second group of holes 122 and the third group of holes 142 positioned on the inner surface 15, the tubular substrate 2 is inserted into the deposition head 1 through the inlet hole 20.

And, when the deposition is performed via the outer surface 13 onto the tubular substrate 2, via the holes of the first group of holes 102, the second group of holes 122 and the third group of holes 142 positioned on the outer surface 13, it is the deposition head 1 inserted into the tubular substrate 2 which is advantageously hollow.

Furthermore, the deposition head 1 according to the invention also has the advantage of being able to be stacked with another deposition head 1 along the axis of rotation R so as to form a chemical vapor deposition system for a tubular substrate 2 comprising at least two deposition heads 1. Thus, it may be envisaged to align along the axis of rotation R and stack several deposition heads 1 in order to adjust the chemical vapor deposition system to tubular substrates 2 of different lengths.

Thus, for a hollow tubular substrate 4, it may be envisaged to introduce a deposition head 1 into the inner part 40 and to use another deposition head 1, as shown in FIG. 1, in which the hollow tubular substrate 4 is introduced in order to perform a coating on two faces, namely an inner face in the inner part 40 and an outer face of the hollow tubular substrate 4.

In addition, the deposition head 1, according to the invention, can be made as a single piece by additive manufacturing. In particular, the use of additive manufacturing allows greater freedom in the shape of the distribution ducts, namely the first and second precursors and the inert gas, and the evacuation of the streams, which are simple recesses in the deposition head 1. It also makes it possible to avoid assembly and soldering tasks, which are time-consuming and sources of defects, and to achieve further miniaturization of the deposition head 1.

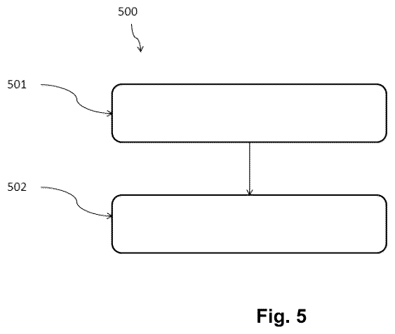

A subject-matter of the invention is also a manufacturing method 500 of the deposition head 1 by additive manufacturing represented in FIG. 5. The manufacturing process 500 comprises the following steps:
obtaining (step 501) an electronic file representing a geometry of a product in which the product is the deposition head,
ordering (step 502) an additive manufacturing device to manufacture, in one or more additive manufacturing steps, the product according to the geometry specified in the electronic file.

Thus, as stated previously, depending on the desired configuration, i.e. an ALD or CVD operation, the deposition head 1 can be adapted via additive manufacturing of the product.

Examples according to the disclosure may be formed using an additive manufacturing process. A common example of additive manufacturing is 3D printing. However, other additive manufacturing methods are available. Rapid prototyping or rapid manufacturing are also terms that can be used to describe additive manufacturing processes. As used here, “additive manufacturing” generally refers to manufacturing processes in which successive layers of material(s) are laid on top of each other to “build” layer-by-layer or “additively manufacture” a three-dimensional component. This is compared to subtractive manufacturing processes (such as milling or drilling), in which the material is successively removed to produce the part. Successive layers generally fuse together to form a monolithic component which can have a variety of integrated sub-components. In particular, the manufacturing process may allow an example of the disclosure to be formed in its entirety and include a variety of features that are not possible when using previous manufacturing processes. The additive manufacturing processes described herein enable manufacturing to any suitable size and shape with various features that may not have been possible using previous manufacturing processes. Additive manufacturing can create complex geometries without using any tools, molds or fixtures, and with little or no waste. Instead of machining components from solid plastic or metal billets, most of which are cut and discarded, the only material used in additive manufacturing is what is needed to form the part, namely the deposition head 1.

Suitable additive manufacturing techniques according to the present disclosure include, for example, Fused Deposition Modelling (FDM), Selective Laser Sintering (SLS), 3D printing such as inkjet and laserjet printing, Stereolithography (SLA), Direct Selective Laser Sintering (Sterolithography or DSLS), Electron Beam Sintering (EBS), Electron Beam Sintering (EBM), Laser Engineered Net Shaping (LENS), Electron Beam Additive Manufacturing (EBAM), Laser Net Shape Manufacturing (LNSM), Direct Metal Deposition (DMD), Digital Light Processing (DLP), Continuous Digital Light Processing (CDLP), Direct Selective Laser Melting (DSLM), Selective Laser Melting (SLM), Direct Metal Laser Melting (DLM), Direct Metal Laser Sintering (DMLS), Material Jetting (MJ), NanoParticle Jetting (NPJ), Drop On Demand (DOD), Binder Jetting (BJ), Multi Jet Fusion (MJF), Laminated Object Manufacturing (LOM) and other known processes. The additive manufacturing processes described here can be used to form components using any suitable material. For example, the material may be plastic, composite, polymer, epoxy, photopolymer resin, metal, or any other suitable material that may be in solid, liquid, powder, sheet, wire, or any other suitable form or combinations thereof. More specifically, according to exemplary embodiments of the present subject-matter, the additively manufactured components described herein may be formed in part, in whole or in a certain combination of materials. These materials are examples of materials suitable for use in additive manufacturing processes that may be suitable for the manufacture of examples described herein.

As indicated above, the additive manufacturing process described herein allows a single component to be formed from several materials. Thus, the examples described herein may be formed from any suitable mixture of the above materials. For example, a component may comprise multiple layers, segments, or parts that are formed using different materials, processes, and/or on different additive manufacturing machines. In this way, components can be constructed that have different materials and material properties to meet the requirements of any particular application. Furthermore, although the components described herein are constructed entirely by additive manufacturing processes, it should be appreciated that in alternative embodiments, all or some of these components may be formed by molding, machining, and/or any other suitable manufacturing process. Indeed, any suitable combination of materials and manufacturing processes can be used to form these components. Additive manufacturing processes generally manufacture components based on three-dimensional (3D) information, for example a three-dimensional computer model (or design file) of the component. Accordingly, the examples described herein include not only products or components as described herein, but also processes for manufacturing such products or components via additive manufacturing and software, firmware or hardware for controlling the manufacture of such products via additive manufacturing.

The structure of the product, i.e. the deposition head 1, can be represented digitally in the form of a design file. A design file, or computer-aided design (CAD) file, is a configuration file that encodes one or more surface or volumetric configurations of the product shape. In other words, a design file represents the geometric arrangement or shape of the product. Design files can take any file format known now or developed later. For example, design files can be in the Stereolithography or “Standard Tessellation Language” (.stl) format that was created for 3D Systems' CAD stereolithography programs, or in the Additive Manufacturing File (.amf) format, which is an American Society of Mechanical Engineers (ASME) standard, an Extensible Markup Language (XML)-based format designed to allow any CAD software to describe the shape and composition of any three-dimensional subject-matter to be manufactured on any additive manufacturing printer. Other examples of design file formats include AutoCAD files (.dwg), Blender files (.blend), Parasolid files (.x_t), 3D Manufacturing Format files (.3mf), Autodesk files (3ds), Collada files (.dae) and Wavefront files (.obj), although many other file formats exist. Design files can be produced using modelling software (e.g., CAD modelling) and/or by scanning the surface of a product to measure the surface configuration of the product.

Once obtained, a design file can be converted into a set of computer-executable instructions that, once executed by a processor, cause the processor to control an additive manufacturing device to produce the deposition head 1 according to the geometric arrangement specified in the design file. The conversion can convert the design file into slices or layers that must be formed sequentially by the additive manufacturing device. Instructions (also known as geometric code or “G-code”) can be calibrated to the specific additive manufacturing device and can specify the exact location and amount of material to be formed at each step of the manufacturing process. As discussed above, forming can be done by deposition, sintering or any other form of additive manufacturing process. The code or instructions can be translated between different formats, converted into a set of data signals and transmitted, received as a set of data signals and converted into code, stored, etc., if necessary. The instructions may be input to the additive manufacturing system and may come from a part designer, intellectual property (IP) provider, design company, the operator or owner of the additive manufacturing system, or other sources. An additive manufacturing system may execute instructions to manufacture the product using any of the technologies or processes described herein. Design files or computer-executable instructions may be stored on a computer-readable storage medium (transitory or non-transitory) (e.g. memory, storage system, etc.) storing code, or computer-readable instructions, representative of the product to be manufactured. As noted, the code or computer-readable instructions define the product that can be used to physically generate the deposition head 1, when the code or instructions are executed by an additive manufacturing system. For example, instructions may include a precisely defined 3D model of the product and may be generated from one of a number of well-known computer-aided design (CAD) software systems such as AutoCAD®, TurboCAD®, DesignCAD 3D Max, etc. Alternatively, a model or prototype of the component can be scanned to determine the three-dimensional information of the component.

Another subject-matter of the invention is a computer program product, the computer program comprising computer-executable instructions which, when executed by a processor, cause the processor to order an additive manufacturing device to manufacture the deposition head 1.

Accordingly, by ordering an additive manufacturing device according to computer-executable instructions, the additive manufacturing device may be instructed to print one or more parts of the deposition head 1. These can be printed in assembled or non-assembled form. Preferably, the deposition head 1 is printed in an assembled form or in a single piece. For example, different sections of the product can be printed separately (as a non-assembled parts kit) and then assembled. Alternatively, and preferably, the individual parts can be printed in an assembled form. In consideration of the above, the embodiments comprise additive manufacturing processes. This includes the steps of obtaining a design file representing the product and instructing an additive manufacturing device to manufacture the product in an assembled or non-assembled form according to the design file. The additive manufacturing device may comprise a processor that is configured to automatically convert the design file into computer-executable instructions to control the manufacture of the product. In these embodiments, the design file itself can automatically cause product to be produced once entered into the additive manufacturing device. Accordingly, in this embodiment, the design file itself can be considered as computer-executable instructions that cause the additive manufacturing device to manufacture the product. Alternatively, the design file can be converted into instructions by an external computer system, with the resulting computer-executable instructions being provided to the additive manufacturing device. In view of the above, the design and manufacture of the subject implementations and the operations described in this specification may be performed using digital electronic circuits, or in software, firmware or computer hardware, including the structures described in this specification and their structural equivalents, or in combinations of one or more of them. For example, the hardware may include processors, microprocessors, electronic circuits, electronic components, integrated circuits, etc. The implementations of the subject described in this specification may be carried out using one or more computer programs, i.e. one or more computer program instruction modules, coded on a computer storage medium for execution by or to order the operation of a data processing device. Alternatively or additionally, program instructions may be coded onto an artificially generated propagated signal, for example, a machine-generated electrical, optical or electromagnetic signal to code information to be transmitted to a suitable receiving device for execution by a data processing device. A computing storage medium may be, or be included in, a computer-readable storage device, a computer-readable storage substrate, an array or a random or serial access memory device, or a combination of one or more thereof. Furthermore, while a computing storage medium is not a propagated signal, a computer storage medium may be a source or destination of computer program instructions encoded in an artificially generated propagated signal. The computing storage medium may also be, or be included in, one or more separate physical components or media (e.g. multiple CDs, disks, or other storage devices). Although additive manufacturing technology is described here as enabling the manufacture of complex subject-matters by constructing subject-matters point-by-point, layer-by-layer, typically in a vertical direction, other manufacturing processes are possible and within the scope of the present topic. For example, while the description herein refers to the addition of material to form successive layers, a person skilled in the art will appreciate that the processes and structures described herein can be put into practice with any additive manufacturing technique or other manufacturing technology. Other techniques include injection molding or manufacturing by low-pressure elastomer casting.

1. A chemical vapor deposition head for a tubular substrate comprising:
a first opening for receiving a first inlet gas stream transporting a first precursor,
a second opening for receiving a second inlet gas stream transporting a second precursor,
a third opening for receiving a third inlet inert gas stream,
a surface configured to allow the deposition of the first gas stream, the second gas stream, and the third inert gas stream on the tubular substrate, the surface having a cylindrical shape so as to allow the insertion of the tubular substrate into the deposition head or of the deposition head into the tubular substrate,
a first network of distribution ducts connecting the first opening of the first gas stream to a first group of holes extending over the surface of the deposition head,
a second network of distribution ducts connecting the second opening of the second gas stream to a second group of holes extending over the surface of the deposition head,
a third network of distribution ducts connecting the third opening of the third inert gas stream to a third group of holes extending over the surface of the deposition head, a hole of the first or second group of holes being adjacent on either side to a hole of the third group of holes along an axis of rotation R of the deposition head,
the first, second, and third distribution duct networks having respectively at least one first, second, and third expansion prechamber comprised in the deposition head,
the tubular substrate configured to perform a relative back-and-forth movement along the axis of rotation R of the deposition head.

2. The deposition head according to claim 1, wherein the at least one first, second and third expansion prechambers extend successively in a direction of the axis of rotation R of the deposition head.

3. The deposition head according to claim 1, wherein the at least one first expansion prechamber of the first distribution duct network is connected to the first group of holes via a first channel, the internal volume of the first channel being smaller than the volume of the at least one first expansion prechamber of the first distribution duct network, wherein the at least one second expansion prechamber of the second distribution duct network is connected to the second group of holes via a second channel, the internal volume of the second channel being smaller than the volume of the at least one second expansion prechamber of the second distribution duct network, wherein the at least one expansion prechamber of the third distribution duct network is connected to the third group of holes by a third channel, the internal volume of the third channel being smaller than the volume of the at least one third expansion prechamber of the third distribution duct network.

4. The deposition head according to claim 1, wherein the first, second, and third distribution ducts are non-intersecting.

5. The deposition head according to claim 1, comprising a fourth distribution duct connected to a fourth group of holes extending over the inner section of the deposition head, the fourth duct enabling the evacuation of the third inert gas stream to a fourth discharge opening of the deposition head.

6. The deposition head according to claim 1, wherein the holes of the first, second and third groups of holes are straight slots parallel to each other.

7. The deposition head according to claim 1, wherein a deposition distance between the holes of the first, second and third groups of holes and the tubular substrate, inserted into the deposition head, is less than two hundred micrometers.

8. The deposition head according to claim 1, wherein a deposition distance between the holes of the first, second and third groups of holes and the tubular substrate, inserted into the deposition head, is greater than fifty micrometers.

9. The deposition head according to claim 1, comprising a first stream receiving face comprising the first, second and third openings and a second stream receiving face comprising first, second and third secondary stream openings, respectively mirroring the first, second and third openings of the first receiving face according to a plane P passing perpendicularly through the axis of rotation R of the deposition head.

10. The deposition head according to claim 1, wherein the first gas stream is an oxidizing precursor.

11. The deposition head according to claim 1, wherein the second gas stream is a metal precursor.

12. A chemical vapor deposition system of a tubular substrate comprising at least two deposition heads according to claim 1.

13. A computer program product, said computer program comprising computer-executable instructions which, when executed by a processor, cause the processor to order an additive manufacturing device to manufacture the deposition head according to claim 1.

14. A method of manufacturing the deposition head according to claim 1 by additive manufacturing, the method comprising the following steps: obtaining an electronic file representing a geometry of a product in which the product is the deposition head and ordering an additive manufacturing device to manufacture, in one or more additive manufacturing steps, the product according to the geometry specified in the electronic file.
